(19) United States
(12) Patent Application Publication
(10) Pub. No.: US 2023/0402562 A1
(43) Pub. Date: Dec. 14, 2023

(54) TRANSFERRING APPARATUS CONFIGURED TO TRANSFER ELECTRONIC COMPONENT, METHOD OF BONDING ELECTRONIC COMPONENT, AND METHOD FOR MANUFACTURING LIGHT-EMITTING DIODE DISPLAY

(71) Applicant: Stroke Precision Advanced Engineering Co., Ltd., Taoyuan City (TW)

(72) Inventors: Chingju Lin, Taoyuan City (TW); Jia Wei Huang, Taoyuan City (TW)

(73) Assignee: Stroke Precision Advanced Engineering Co., Ltd., Taoyuan City (TW)

(21) Appl. No.: 18/304,319

(22) Filed: Apr. 20, 2023

(30) Foreign Application Priority Data
Jun. 13, 2022 (TW) 111121900

(51) Int. Cl. H01L 33/00

(52) U.S. Cl. CPC H01L 33/005

(57) ABSTRACT

A transferring apparatus configured to transfer an electronic component includes a first carrier, a second carrier, an actuator mechanism, and a flexible push generator. The first carrier is configured to carry an objective substrate, and the second carrier is configured to carry a transfer substrate. The actuator mechanism is configured to actuate the first carrier and the second carrier to move close to and away from each other. The flexible push generator is disposed near the first carrier or the second carrier and generates a flexible push to the carried objective substrate or transfer substrate when the first carrier and the second carrier are actuated in a way close to each other. A method of bonding an electronic component and a method for manufacturing a light-emitting diode display are also provided.

### CROSS-REFERENCE TO RELATED APPLICATION

This application claims the priority benefit of Taiwan application serial no. 111121900, filed on Jun. 13, 2022. The entirety of the above-mentioned patent application is hereby incorporated by reference herein and made a part of this specification.

### BACKGROUND

### Technical Field

The disclosure relates to a transferring apparatus configured to transfer an electronic component, a method of bonding an electronic component, and a method for manufacturing a light-emitting diode display.

### Description of Related Art

A semiconductor device is usually grown on a growth substrate by means of epitaxy. However, as the various applications of semiconductor devices change, the semiconductor device may not necessarily stay on the original growth substrate when finally on a finished product. The semiconductor device may be transferred onto a transfer substrate, and finally transferred onto an objective substrate and form a final finished product.

When transferring the semiconductor device from the transfer substrate to the objective substrate is desired, one method is to face the front sides of the transfer substrate and the objective substrate, and bond the transfer substrate and the objective substrate. The conventional bonding method is to directly bond the transfer substrate and the objective substrate after aligning the transfer substrate and the objective substrate with a mechanism, so that the planes of the two substrates are in full contact. However, the coplanar state of the two planes is not easy to be adjusted by the mechanism, and the flatness requirements of the transfer substrate and the objective substrate are high, so the fabrication is time-consuming and costly. In addition, when the transfer substrate and the objective substrate are bonded by the conventional bonding method, the situation of non-uniform bonding force is prone to occur, and the uniformity of bonding cannot be well controlled.

### SUMMARY

The disclosure provides a transferring apparatus configured to transfer an electronic component, which may apply force evenly to the substrate to produce a good bonding effect.

The disclosure provides a method of bonding an electronic component, which may apply force evenly to the substrate to produce a good bonding effect.

The disclosure provides a method for manufacturing a light-emitting diode display, which has a higher yield and can fix the light-emitting diode more accurately.

An embodiment of the disclosure provides a transferring apparatus configured to transfer an electronic component, which includes a first carrier, a second carrier, an actuator mechanism, and a flexible push generator. The first carrier is configured to carry an objective substrate, and the second carrier is configured to carry a transfer substrate. The actuator mechanism is configured to actuate the first carrier and the second carrier to move close to and away from each other. The flexible push generator is disposed near the first carrier or the second carrier and generates a flexible push to the carried objective substrate or transfer substrate when the first carrier and the second carrier are actuated in a way close to each other.

In an embodiment of the disclosure, the flexible push generator includes a gas-filled airbag.

In an embodiment of the disclosure, the flexible push generator includes a pouch, and the pouch is configured to be connected to a gas pump mechanism. When the first carrier and the second carrier are actuated in a way close to each other, the gas pump mechanism inflates the pouch, and when the first carrier and the second carrier are actuated in a way away from each other, the gas pump mechanism extracts at least a portion of the gas out of the pouch.

In an embodiment of the disclosure, the transferring apparatus configured to transfer the electronic component further includes a laser generator, which is disposed near the first carrier or the second carrier, and configured to generate a laser beam on the carried objective substrate and/or transfer substrate.

An embodiment of the disclosure provides a method of bonding an electronic component, which includes: a transfer substrate including a side on which the electronic component is disposed is provided; an objective substrate having a bonded side and a non-bonded side is provided; the side of the transfer substrate provided with the electronic component is made to face the bonded side of the objective substrate, and the transfer substrate in which the electronic component is disposed face the bonded side of the objective substrate; the transfer substrate and the objective substrate are made to approach each other until the electronic component contacts the bonded side of the objective substrate; a flexible push is applied to a side of the transfer substrate on which the electronic component is not disposed or the non-bonded side of the objective substrate; and an energy beam is applied to the electronic component, so that the electronic component is released from the transfer substrate and bonded on the bonded side of the objective substrate.

In an embodiment of the disclosure, the flexible push is generated by an airbag pushing the side of the transfer substrate that is not provided with the electronic component or the non-bonded side of the objective substrate.

In an embodiment of the disclosure, the airbag is produced by inflating a pouch.

In an embodiment of the disclosure, the energy beam is a laser beam.

In an embodiment of the disclosure, the electronic component is a light-emitting diode.

In an embodiment of the disclosure, the objective substrate is a thin film transistor substrate.

An embodiment of the disclosure provides a method for manufacturing a light-emitting diode display, which includes bonding a light-emitting diode using the above-mentioned method of bonding the electronic component.

In the transferring apparatus configured to transfer the electronic component, the method of bonding the electronic component, and the method for manufacturing the light-emitting diode display according to the embodiments of the disclosure, since a flexible push is generated to the objective substrate or the transfer substrate, and the flexible push may make the objective substrate or the transfer substrate evenly stressed, a good and uniform bonding effect may be produced between the objective substrate and the transfer substrate, thereby improving the manufacturing yield, and fixing the electronic component or the light-emitting diode more accurately.

### BRIEF DESCRIPTION OF THE DRAWINGS

FIG. 1 is a three-dimensional schematic diagram of a transferring apparatus configured to transfer an electronic component according to an embodiment of the disclosure.

FIGS. 2A to 2D are schematic cross-sectional views of a transferring apparatus configured to transfer an electronic component in four different operating stages according to another embodiment of the disclosure.

FIGS. 3A to 3E are schematic cross-sectional views of a transferring apparatus configured to transfer an electronic component in five different operating stages according to yet another embodiment of the disclosure.

### DESCRIPTION OF THE EMBODIMENTS

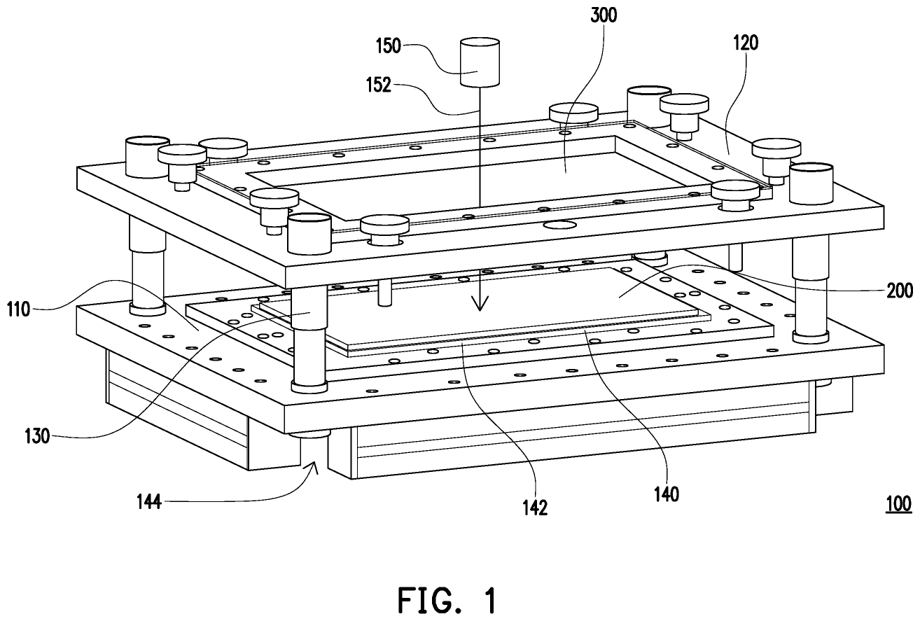

FIG. 1 is a three-dimensional schematic diagram of a transferring apparatus configured to transfer an electronic component according to an embodiment of the disclosure. Referring to FIG. 1, an apparatus 100 configured to transfer an electronic component in the embodiment includes a first carrier 110, a second carrier 120, an actuator mechanism 130, and a flexible push generator 140. The first carrier 110 is configured to carry an objective substrate 200, and the second carrier 120 is configured to carry a transfer substrate 300. The actuator mechanism 130 is configured to actuate the first carrier 110 and the second carrier 120 to move close to and away from each other. The actuator mechanism 130 is, for example, a motor, a bolt, other actuator mechanisms or a combination thereof. The flexible push generator 140 is disposed near the first carrier 110 or the second carrier 120 (in FIG. 1, the first carrier 110 is taken as an example), which may generate a flexible push to the carried objective substrate 200 or transfer substrate 300 (in FIG. 1, the objective substrate 200 is taken as an example) when the first carrier 110 and the second carrier 120 are actuated in a way close to each other.

In the embodiment, the flexible push generator 140 includes a gas-filled airbag. Specifically, the flexible push generator 140 includes a pouch 142, which is configured to be connected to a gas pump mechanism 144. When the first carrier 110 and the second carrier 120 are actuated in a way close to each other, the gas pump mechanism 144 inflates the pouch 142, and when the first carrier 110 and the second carrier 120 are actuated in a way away from each other, the gas pump mechanism 144 extracts at least a portion of gas out of the pouch. The gas pump mechanism 144 is, for example, an air extracting pump or other apparatuses with functions of air extraction and air intake.

In the embodiment, the apparatus 100 configured to transfer the electronic component further includes a laser generator 150, which is disposed near the first carrier 110 or the second carrier 120 (in FIG. 1, the second carrier 120 is taken as an example), and configured to generate a laser beam 152 on the carried objective substrate 200 and/or transfer substrate 300. In the embodiment, the laser generator 150 is a laser light source, and the laser beam 152 is, for example, an infrared laser beam, but the disclosure is not limited thereto. In other embodiments, the laser beam 152 may also be a visible laser beam or an ultraviolet laser beam.

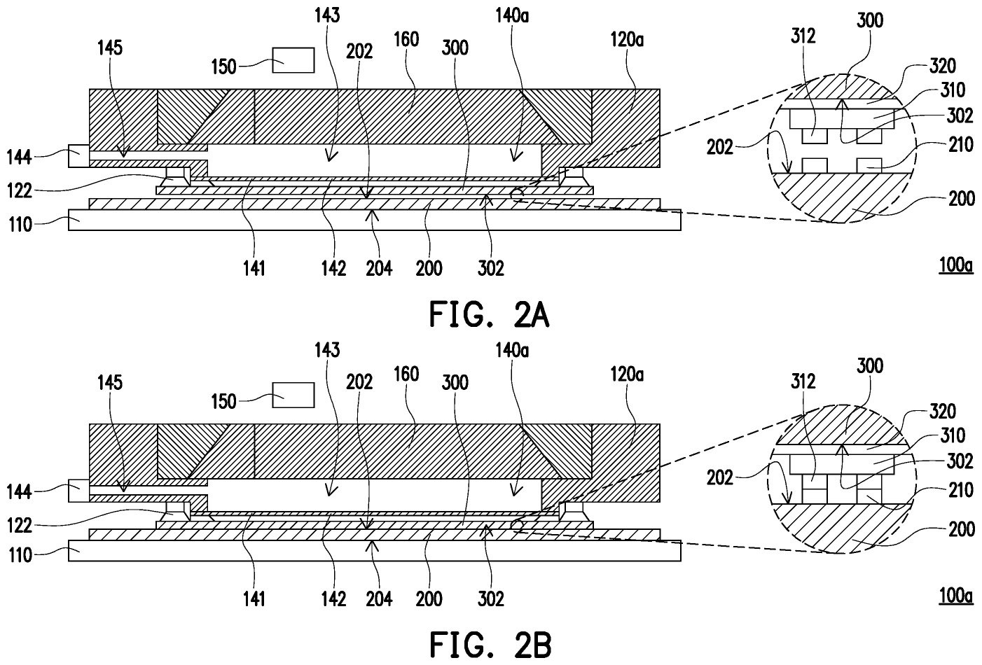

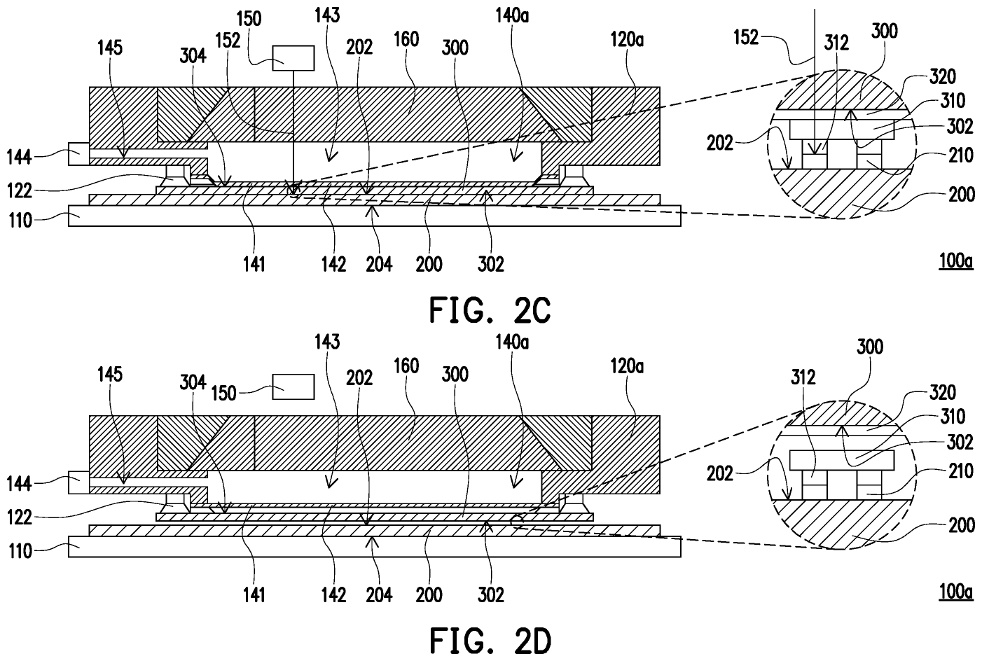

FIGS. 2A to 2D are schematic cross-sectional views of a transferring apparatus configured to transfer an electronic component in four different operating stages according to another embodiment of the disclosure. Referring to FIG. 2A first, an apparatus 100a configured to transfer an electronic component in the embodiment is similar to the apparatus 100 configured to transfer the electronic component in FIG. 1, and the main differences between the two are as follows. A flexible push generator 140a of the apparatus 100a configured to transfer the electronic component in the embodiment is disposed near a second carrier 120a. Specifically, a transparent cover plate 160 (such as a quartz cover plate, but the disclosure is not limited thereto) is disposed on the second carrier 120a, and an elastic film 141 is disposed under the second carrier 120a. The space between the elastic film 141, the transparent cover plate 160, and the second carrier 120a forms a pressure chamber 143 in the pouch 142, and the pressure chamber 143 communicates with the gas pump mechanism 144 through a gas channel 145.

The apparatus 100a configured to transfer the electronic component in the embodiment and the apparatus 100 configured to transfer the electronic component in the above-mentioned embodiment may both be configured to implement a method of bonding an electronic component in an embodiment of the disclosure. The following uses the apparatus 100a configured to transfer the electronic component as an example for description. The method of bonding the electronic component in the embodiment includes the following steps. First, referring to FIG. 2A, a transfer substrate 300 is provided, and at least one electronic component 310 (in the embodiment, for example, multiple electronic components 310, and the partial enlarged view in FIG. 2A shows an electronic component 310 as an example) is disposed on a side (such as a surface 302) of the transfer substrate 300. In addition, an objective substrate 200 is provided, which has a bonded side 202 and a non-bonded side 204, and multiple bumps 210 corresponding to the electronic components 310 may be disposed on the bonded side 202. On the other hand, the first carrier 110 carries the objective substrate 200, and the second carrier 120a may suck the transfer substrate 300 through a suction nozzle 122. In the embodiment, the transfer substrate 300 is a transparent substrate that may allow the laser beam 152 to pass through, such as a glass substrate, and the electronic component 310 is fixed on the transfer substrate 300 through an adhesive layer 320. Generally speaking, the chip of the electronic component 310 may be fabricated on a growth substrate by an epitaxial process. After the fabrication is completed, the electronic component 310 is transferred from the growth substrate to the transfer substrate 300, and the electronic component 310 is fixed on the transfer substrate 300 through the adhesive layer 320. In the embodiment, the electronic component 310 is a light-emitting diode, such as a light-emitting diode chip, but the disclosure is not limited thereto. In other embodiments, the electronic component 310 may also be other chips. In the embodiment, the objective substrate 200 is a thin film transistor substrate. However, in other embodiments, the objective substrate 200 may also be other types of substrates, such as a silicon substrate, a circuit board, etc., but the disclosure is not limited thereto. For example, the objective substrate 200 may be a substrate made of a material less likely to absorb the laser beam 152, which is a preferable choice.

In the step of FIG. 2A, the transfer substrate 300 may be aligned with the objective substrate 200 and a certain gap is maintained between the two, for example, pads 312 of the electronic components 310 on the transfer substrate 300 are aligned with the bumps 210 on the objective substrate 200.

Next, as shown in FIG. 2B, the side of the transfer substrate 300 provided with the electronic component 310 (i.e., the surface 302) is made to face the bonded side 202 of the objective substrate 200, and the transfer substrate 300 and the objective substrate 200 are made to approach each other until the electronic component 310 contacts the bonded side 202 of the objective substrate 200, specifically, for example, until the pad 312 on the electronic component 310 abuts against the bump 210 on the bonded side 202. For example, the transfer substrate 300 may be placed on the objective substrate 200, and one side of the transfer substrate 300 may first be in contact with the objective substrate 200, and then the other side of the transfer substrate 300 may be in contact with the objective substrate 200. Alternatively, each side of the transfer substrate 300 may be lowered together to be in contact with the objective substrate 200 at the same time.

Afterwards, as shown in FIG. 2C, a flexible push is applied to a side of the transfer substrate 300 on which the electronic component 310 is not disposed (that is, a surface 304) or the non-bonded side 204 of the objective substrate 200, and in FIG. 2C, the flexible push is applied to the surface 304 of the transfer substrate 300. In the embodiment, the gas pump mechanism 144 may be used to inflate the pressure chamber 143 to inflate the pouch 142, that is, to deform the elastic film 141 downward to compress the transfer substrate 300, and the elastic film 141 exerts a flexible push to the transfer substrate 300. That is to say, the above-mentioned flexible push is generated by an airbag created by the pouch 142 being inflated pushing the side of the transfer substrate 300 that is not provided with the electronic component 310 (that is, the surface 304) or the non-bonded side 204 of the objective substrate 200.

In addition, an energy beam (for example, a laser beam 152) is applied to the electronic component 310, so that the electronic component 310 is released from the transfer substrate 300, and bonded on the bonded side 202 of the objective substrate 200. In the embodiment, the laser generator 150 may be used to apply the laser beam 152 to the pad 312 of the electronic component 310 and the bump 210, so that the bump 210 is in a molten state, and then bonded together with the pad 312. In the embodiment, the laser generator 150 may make the laser beam 152 perform linear scanning or surface scanning, so as to scan to different electronic components 310, or the laser generator 150 may also make the laser beam 152 emit at a specific position at a fixed point, so as to accurately emit at multiple different electronic components 310 at different times. In other embodiments, the energy beam may also be a non-laser general beam, such as a beam converging on the electronic component 310. In the embodiment, the elastic film 141 is, for example, a silicone film, which is resistant to the laser beam 152 and may be penetrated by the laser beam 152 without being burned.

Next, as shown in FIG. 2D, the gas pump mechanism 144 discharges some of the gas in the pouch 142 to release the air pressure in the pressure chamber 143, thereby restoring the elastic film 141 to the original shape. On the other hand, the second carrier 120a is moved away from the first carrier 110. At this time, since the bonding force between the pad 312 and the bump 210 is greater than the adhesive force of the adhesive layer 320 to the electronic component 310, the electronic component 310 is separated from the adhesive layer 320 and released from the transfer substrate 300, and is fixed on the objective substrate 200 through the bump 210. A thin film transistor circuit electrically connected to the bump 210 may be provided on the objective substrate 200. Therefore, after the step of FIG. 2D is completed, the objective substrate 200 and the electronic component 310 thereon may form a light-emitting diode display, and the electronic components 310 are arranged in an array on the objective substrate 200 to become pixels of the objective substrate 200. Therefore, in the embodiment, the method of bonding the electronic component shown in FIGS. 2A to 2D may be regarded as a method for manufacturing a light-emitting diode display.

In another embodiment, in the step of FIG. 2C, the laser beam 152 may be further applied to the adhesive layer 320 to debond the adhesive force of the adhesive layer 320 to the electronic component 310, which facilitates the step of FIG. 2D, in which the electronic component 310 is more easily released from the adhesive layer 320.

In addition, after the electronic component 310 is separated from the adhesive layer 320 and released from the transfer substrate 300, the transfer substrate 300 may be unloaded from the second carrier 120a, and then the second carrier 120a is loaded with another transfer substrate 300 provided with the electronic component 310. Next, the second carrier 120a may move to other areas on the objective substrate 200 where the electronic components 310 are not disposed, and then transfer the electronic components 310 to the entire objective substrate 200 step by step. However, in another embodiment, it may also be that the electronic components 310 on one transfer substrate 300 cover the electronic components 310 required by the entire objective substrate 200. In this case, only one transfer is required to provide all the electronic components 310 required by the objective substrate 200.

In the apparatus 100 or 100a configured to transfer the electronic component and the method of bonding the electronic component in the embodiment, since a flexible push is generated on the objective substrate 200 or the transfer substrate 300, and the flexible push may make the objective substrate 200 or the transfer substrate 300 evenly stressed, a good and uniform bonding effect may be produced between the objective substrate 200 and the transfer substrate 300, thereby improving the manufacturing yield, and fixing the electronic component 310 more accurately. In the embodiment, the objective substrate 200 and the transfer substrate 300 may be subjected to a proper and uniform bonding force by precisely controlling the air pressure of the gas in the pouch 142. In this way, the objective substrate 200 and the transfer substrate 300 may tolerate larger tolerances during manufacture and still be bonded together uniformly by the flexible push, and the coplanarity requirements of the two substrates may be lower, which can effectively reduce the manufacturing costs and man-hours of the objective substrate 200 and the transfer substrate 300. In an embodiment, the air pressure of the gas in the pouch 142 may be controlled at an appropriate air pressure by a precision pressure regulating valve or an air pressure proportional valve, for example, the minimum may be controlled at 0.05 kg/cm², so as to effectively control the parameters of the bonding force.

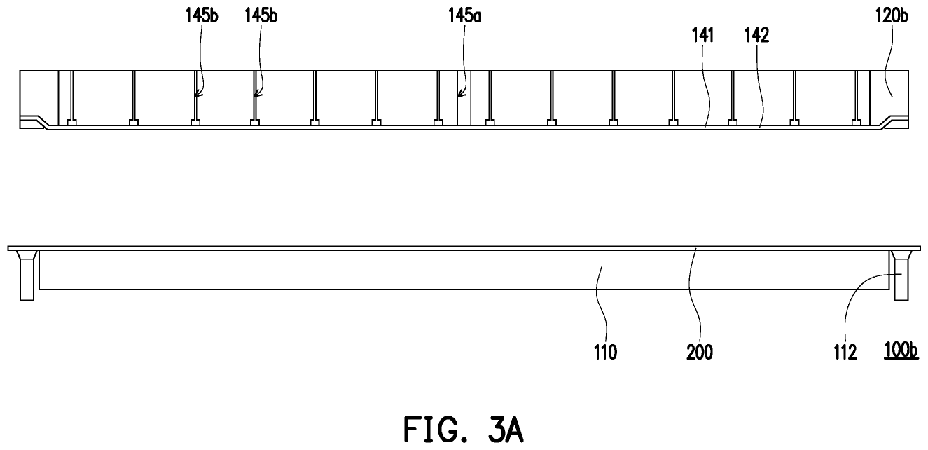

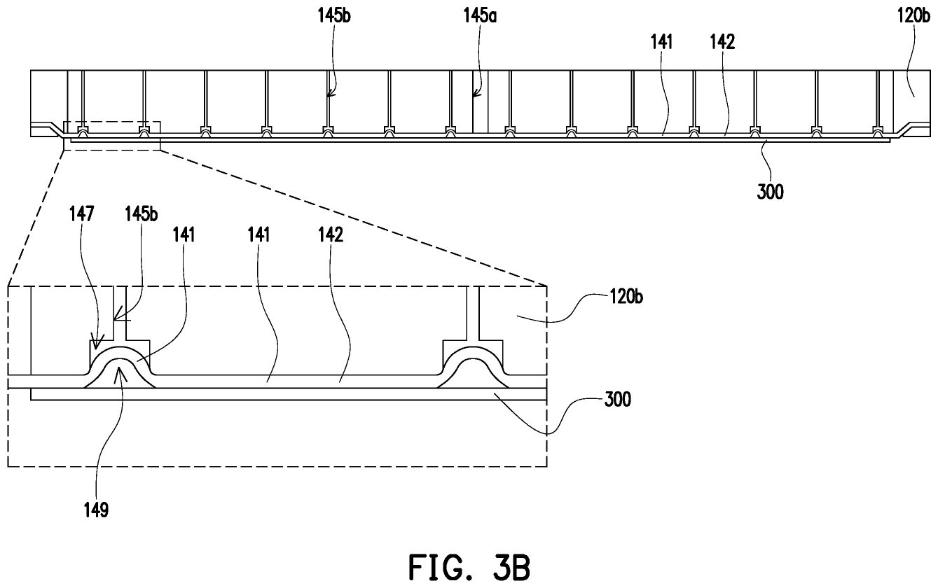

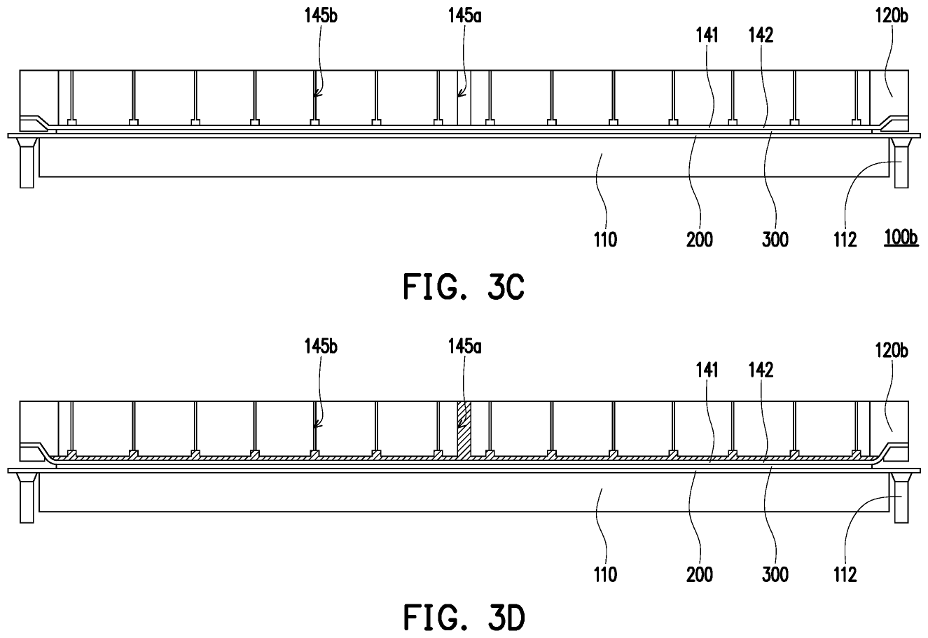

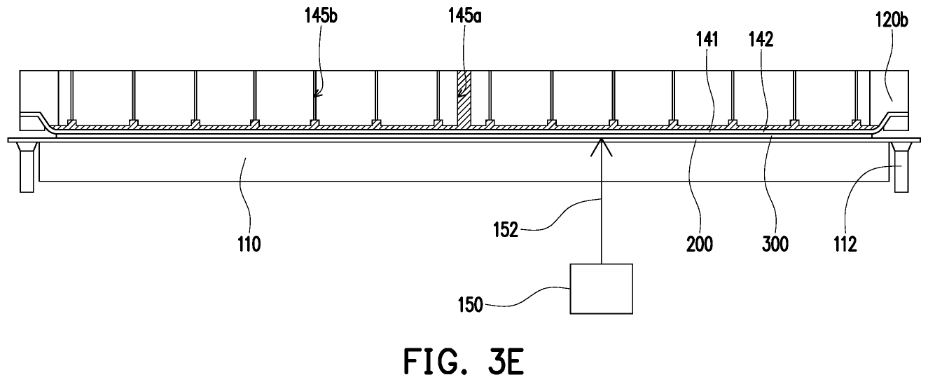

FIGS. 3A to 3E are schematic cross-sectional views of a transferring apparatus configured to transfer an electronic component in five different operating stages according to yet another embodiment of the disclosure. Referring to FIGS. 3A to 3E, an apparatus 100b configured to transfer an electronic component in the embodiment is similar to the apparatus 100a configured to transfer the electronic component in FIGS. 2A to 2D, and the differences between the two are as follows. A second carrier 120b of the embodiment has a first gas channel 145a and multiple second gas channels 145b, one end of which is connected to a gas pump mechanism (not shown in the figure), and the other end is connected to the upper surface of the elastic film 141. In addition, a suction nozzle 112 may be disposed on the edge of the first carrier 110 to be attached to the objective substrate 200. In the embodiment, the objective substrate 200 is, for example, a glass substrate with a thin film transistor circuit disposed on the surface, but the disclosure is not limited thereto. The apparatus 100b configured to transfer the electronic component of the embodiment may be configured to implement the method of bonding the electronic component of the another embodiment of the disclosure. After the objective substrate 200 is ready as shown in FIG. 3A, the step of FIG. 3B may be carried out, that is, the gas pump mechanism performs air extraction on the second gas channel 145b, so that the second carrier 120b is attached to the transfer substrate 300. At this time, a vacuum chamber 147 is generated at the lower end of the second gas channel 145b to be attached to the elastic film 141 and locally deform the elastic film 141. A vacuum chamber 149 is also generated between the partially deformed part of the elastic film 141 and the transfer substrate 300, so that the transfer substrate 300 is attached to the elastic film 141.

Next, as shown in FIG. 3C, after the transfer substrate 300 is aligned with the objective substrate 200, the transfer substrate 300 is lightly touched to the objective substrate 200, placed on the objective substrate 200 by natural gravity, and the gas pump mechanism is stopped performing air extraction on the second gas channel 145b. Here, the alignment between the transfer substrate 300 and the objective substrate 200 refers to, for example, aligning the pads 312 of the electronic components 310 on the transfer substrate with the bumps 210 on the objective substrate 200. The details of the electronic component 310, the pad 312, and the bump 210 are not shown again in FIGS. 3A to 3E, and the figures of the electronic component 310, the pad 312, and the bump 210 may refer to FIGS. 2A to 2D.

Furthermore, as shown in FIG. 3D, the first gas channel 145a is inflated by using the gas pump mechanism, that is, the positive pressure gas is used to fill the first gas channel 145a with positive pressure, and at this time, the pouch 142 formed by the elastic film 141 and the second carrier 120b is inflated to expand, so that the elastic film 141 deforms downward and applies a flexible push to the transfer substrate 300. At this time, the second carrier 120b also slowly rises to a certain height, so that the transfer substrate 300 is merely subjected to the flexible push exerted by the pouch 142, and is not directly subjected to the contact force of the second carrier 120b.

After that, as shown in FIG. 3E, in the state where the pouch 142 is maintained inflated, the laser generator 150 is used to apply the laser beam 152 to the electronic component 310, so that the electronic component 310 is released from the transfer substrate 300, and bonded on the bonded side 202 of the objective substrate 200. The details of bonding have been described in detail in the embodiment of FIG. 2C and are not repeated here. In the embodiment, the laser generator 150 and the pouch 142 are disposed on opposite sides of the transfer substrate 300, but the disclosure is not limited thereto. In the embodiment of FIG. 2C, the laser generator 150 and the pouch 142 are disposed on the same side of the transfer substrate 300.

Thereafter, the gas pump mechanism may be used again to perform air extraction on the second gas channel 145b, so that the second carrier 120b is attached to the transfer substrate 300 again, and moves the transfer substrate 300 away from the objective substrate 200, thereby making the electronic component 310 released from the transfer substrate 300 and remain on the objective substrate 200.

In summary, in the transferring apparatus configured to transfer the electronic component, the method of bonding the electronic component, and the method for manufacturing the light-emitting diode display according to the embodiments of the disclosure, since a flexible push is generated to the objective substrate or the transfer substrate, and the flexible push may make the objective substrate or the transfer substrate evenly stressed, a good and uniform bonding effect may be produced between the objective substrate and the transfer substrate, thereby improving the manufacturing yield, and fixing the electronic component or the light-emitting diode more accurately.

What is claimed is:

1. A transferring apparatus configured to transfer an electronic component comprising:
a first carrier, configured to carry an objective substrate;
a second carrier, configured to carry a transfer substrate;
an actuator mechanism, configured to actuate the first carrier and the second carrier to move close to and away from each other; and
a flexible push generator, disposed near the first carrier or the second carrier and generating a flexible push to the objective substrate or the transfer substrate that are carried when the first carrier and the second carrier are actuated in a way close to each other.

2. The transferring apparatus configured to transfer the electronic component according to claim 1, wherein the flexible push generator comprises a gas-filled airbag.

3. The transferring apparatus configured to transfer the electronic component according to claim 1, wherein the flexible push generator comprises a pouch, the pouch is configured to be connected to a gas pump mechanism, when the first carrier and the second carrier are actuated in a way close to each other, the gas pump mechanism inflates the pouch, and when the first carrier and the second carrier are actuated in a way away from each other, the gas pump mechanism extracts at least a portion of gas out of the pouch.

4. The transferring apparatus configured to transfer the electronic component according to claim 1, further comprising a laser generator, disposed near the first carrier or the second carrier, and configured to generate a laser beam on the objective substrate and/or the transfer substrate.

5. A method of bonding an electronic component, comprising:
providing a transfer substrate comprising a side on which the electronic component is disposed;
providing an objective substrate having a bonded side and a non-bonded side;
making the side of the transfer substrate in which the electronic component is disposed face the bonded side of the objective substrate;
making the transfer substrate and the objective substrate approach each other until the electronic component contacts the bonded side of the objective substrate;
applying a flexible push to a side of the transfer substrate on which the electronic component is not disposed or the non-bonded side of the objective substrate; and
applying an energy beam to the electronic component, so that the electronic component is released from the transfer substrate and bonded on the bonded side of the objective substrate.

6. The method of bonding the electronic component according to claim 5, wherein the flexible push is generated by an airbag pushing the side of the transfer substrate that is not provided with the electronic component or the non-bonded side of the objective substrate.

7. The method of bonding the electronic component according to claim 6, wherein the airbag is produced by inflating a pouch.

8. The method of bonding the electronic component according to claim 5, wherein the energy beam is a laser beam.

9. The method of bonding the electronic component according to claim 5, wherein the electronic component is a light-emitting diode.

10. The method of bonding the electronic component according to claim 5, wherein the objective substrate is a thin film transistor substrate.

11. A method for manufacturing a light-emitting diode display, comprising bonding a light-emitting diode using the method for bonding the electronic component according to claim 9.
